(19) United States
(12) Patent Application Publication
(10) Pub. No.: US 2025/0331324 A1
(43) Pub. Date: Oct. 23, 2025

(54) INTEGRATED CIRCUIT DEVICE INCLUDING A CROSSTALK REDUCTION STRUCTURE FOR HALF-SHIELD PHASE DETECTION

(71) Applicant: Taiwan Semiconductor Manufacturing Company, Ltd., Hsinchu (TW)

(72) Inventors: Yi-Hsuan Wang, Hsinchu City (TW); Cheng-Yu Huang, Hsinchu (TW); Keng-Yu Chou, Kaohsiung City (TW); Wei-Chieh Chiang, Yuanlin Township (TW)

(21) Appl. No.: 19/254,255

(22) Filed: Jun. 30, 2025

Related U.S. Application Data
(63) Continuation of application No. 18/586,940, filed on Feb. 26, 2024.
(60) Provisional application No. 63/594,453, filed on Oct. 31, 2023.

(51) Int. Cl. H10F 39/00

(52) U.S. Cl. CPC H10F 39/8053; H10F 39/024; H10F 39/8057

(57) ABSTRACT

Some embodiments relate to an integrated circuit (IC) device including a substrate having first photodetector groups respectively associated with a plurality of color pixels and second photodetector groups respectively associated with a plurality of phase detection pixels. Each of the first and second photodetector groups includes one or more photodetectors. The device further includes a grid structure over the substrate, color filters over the substrate, and a crosstalk reduction structure. The grid structure includes light shields, each configured to redirect light away from a corresponding one of the second photodetector groups. Each color filter vertically spans the grid structure at a corresponding one of the first photodetector groups. The crosstalk reduction structure is level with the color filters and limits an amount of the light redirected by the light shield of each of the phase detection pixels to the first photodetector group of a neighboring one of the color pixels.

### REFERENCE TO RELATED APPLICATIONS

This Application is a Continuation of U.S. application Ser. No. 18/586,940, filed on Feb. 26, 2024, which claims the benefit of U.S. Provisional Application No. 63/594,453, filed on Oct. 31, 2023. The contents of the above-referenced Patent Applications are hereby incorporated by reference in their entirety.

### BACKGROUND

Some integrated circuit (IC) manufacturers have integrated aspects of phase detection auto-focus (PDAF) technology in complementary metal-oxide-semiconductor (CMOS) image sensor (CIS) devices. In such devices, the speed associated with PDAF technology may be higher than that associated with other auto-focus technologies, as the device may provide the phase detection data needed for auto-focus functionality on a continual basis with little latency while simultaneously capturing image data.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate schematic cross-sectional and plan views, respectively, of some embodiments of an integrated circuit (IC) device employing a crosstalk reduction structure for half-shield PDAF, according to the present disclosure.

FIGS. 2A through 2F, FIGS. 3 through 8, and FIGS. 9A and 9B illustrate cross-sectional views of some embodiments of an IC device employing a crosstalk reduction structure for half-shield PDAF, according to the present disclosure.

FIGS. 10A through 10P illustrate cross-sectional views of some embodiments of an IC device employing a crosstalk reduction structure for half-shield PDAF, as shown in FIG. 2A, at various stages of manufacture, according to the present disclosure.

FIG. 11 illustrates a block diagram of some embodiments of a methodology of forming an IC device employing a crosstalk reduction structure for half-shield PDAF, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, phase detection auto-focus (PDAF) functionality may be incorporated in a complementary metal-oxide-semiconductor (CMOS) image sensor (CIS) integrated circuit (IC) device by way of a half-shield phase detection pixel design. In such a design, some pixel locations of an image pixel array are occupied by special-purpose phase-detection pixels that incorporate a “half-shield” disposed over a portion (e.g., a left half or a right half) of the associated pixel, thus substantially blocking light from half of the one or more photodetectors associated with the pixel. Processing the data from the phase-detection pixels may produce an indication (e.g., a magnitude and direction) by which a relative distance between an external lens (e.g., a camera lens) and the CIS IC device may be altered to bring an object into focus on the CIS IC device. However, in some designs, some light encountering a half-shield may be improperly directed to a neighboring image pixel, such as by way of total internal reflection (TIR) at a microlens positioned over a photodetector corresponding to the image pixel, thereby possibly increasing the amount of light detected by the image pixel beyond the amount actually associated with that pixel.

To address these issues, the present disclosure provides some embodiments of an IC device that employs a crosstalk reduction structure that may be located in a layer of the IC device that includes color filters for the image pixels and a grid structure that may include the half-shields for the phase detection pixels. In some embodiments, the crosstalk reduction structure may include, for example, additional color filters, anti-reflective coatings (ARCs), and/or variations in width of various segments of the grid structure. Use of the crosstalk reduction structure may reduce the amount of light redirected to a neighboring image pixel by a half-shield. Consequently, potential issues caused by such crosstalk, such as undesirable flaring associated with color pixels, sensitivity variation between color pixels, sensitivity variation between color pixels and phase-detection pixels, and so on, may be mitigated.

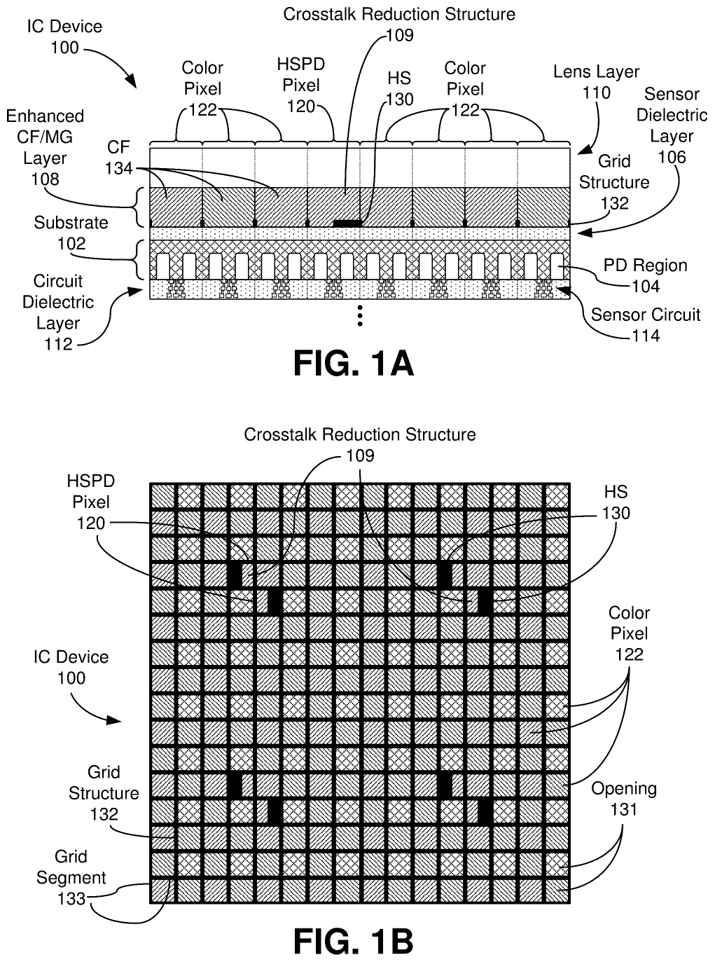

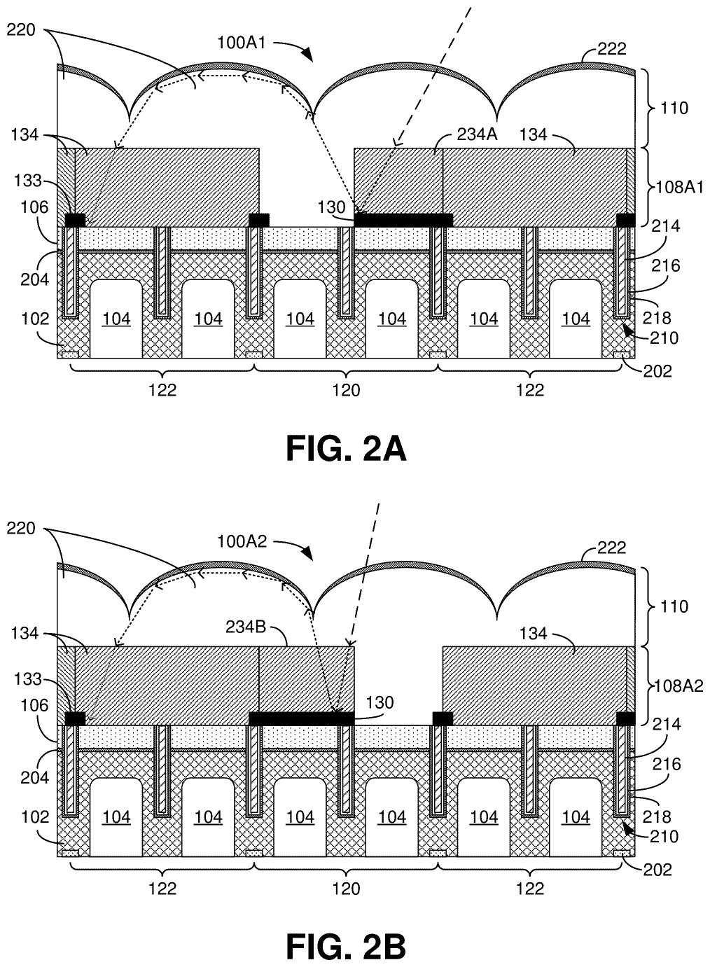

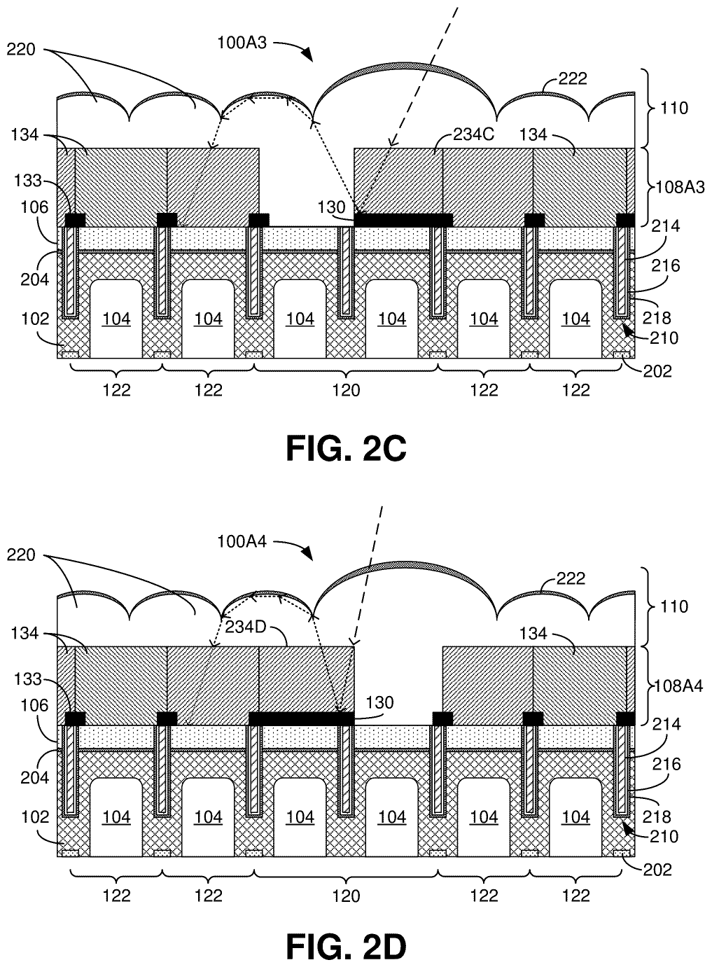

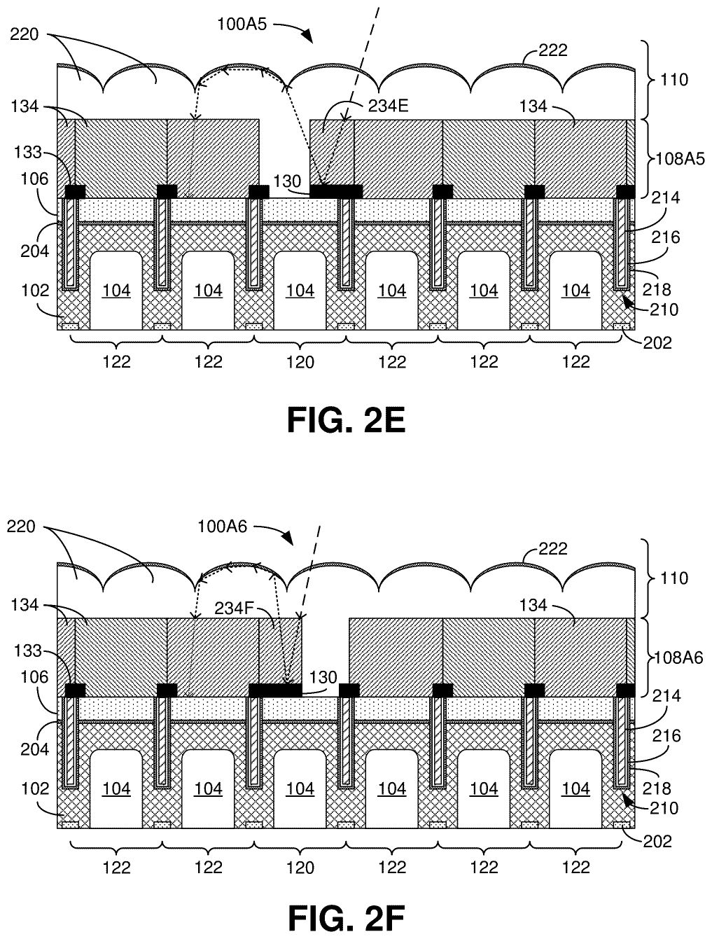

FIGS. 1A and 1B illustrate schematic cross-sectional and plan views, respectively, of some embodiments of an IC device 100 (e.g., an IC imaging device) employing a crosstalk reduction structure for half-shield PDAF, according to the present disclosure. More specifically, FIG. 1A is a schematic cross-sectional view of IC device 100, in which the components of the various layers of IC device 100 that are associated with each pixel are stacked strictly vertically. However, in other embodiments, these same components may be skewed laterally from layer to layer. For example, in some embodiments, the chief ray angle associated with each pixel may vary based on the position of the pixel within a pixel array in the IC device 100. More specifically, pixels at or near the center of the array may have a chief ray angle of approximately zero degrees, resulting in the components of the pixel being stacked substantially vertically. In contrast, pixels near the edge or corner of the array may have a significant chief ray angle that necessitates skewing of the components of such pixels toward the center of the array. In some examples, this component skew may exacerbate potential crosstalk between a phase detection pixel and an imaging pixel. Various embodiments shown in FIGS. 2A through 2F, FIGS. 3 through 8, and FIGS. 9A and 9B depict such skew.

As shown in FIG. 1A, a substrate 102 may include a number of photodetectors (PDs) (e.g., photodiodes or the like) that include PD regions 104 that are formed (e.g., doped or implanted) in substrate 102. In some embodiments, as illustrated in FIG. 1A, two PD regions 104 are included in each pixel. However, one or more PD regions 104 may be employed in each pixel in other embodiments.

Adjacent to substrate 102 may be a circuit dielectric layer 112 that includes sensor circuit 114 (e.g., including various conductive structures, such as copper structures) that is coupled with the photodetectors of substrate 102 (e.g., to transfer the charge generated by photons impacting PD regions 104, to reset the associated photodetectors, and so on). Circuit dielectric layer 112 may include one or more dielectric materials, including, but not limited to, silicon oxide (SiOₓ) (e.g., silicon oxide (SiO₂)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. Additional layers may be disposed under circuit dielectric layer 112 in some embodiments, but such layers are not discussed further herein to simplify the following discussion.

A sensor dielectric layer 106 may be disposed over substrate 102. In some embodiments, sensor dielectric layer 106 may include one or more dielectric materials, such as those listed above in conjunction with circuit dielectric layer 112. Moreover, an enhanced color filter/metal grid (CF/MG) layer 108 may be disposed over sensor dielectric layer 106. As is described in greater detail below, enhanced CF/MG layer 108 includes a crosstalk reduction structure 109 (e.g., an additional color filter) that limits or reduces crosstalk between a half-shield phase detection (HSPD) pixel 120 and a neighboring color pixel 122.

In some embodiments, enhanced CF/MG layer 108 may include a grid structure (e.g., a metal grid (MG)) 132 and a color filter (CF) 134 for each color pixel 122. FIG. 1B illustrates a schematic plan view of FIG. 1B, in which the grid nature of grid structure 132 is shown. As shown, the scale of FIG. 1B is about half of the scale of FIG. 1A to depict a greater number of pixels. Grid structure 132 includes a plurality of grid segments 133 that form a plurality of openings 131 through which light may pass before encountering PD regions 104 associated with color pixels 122 and half-shield phase detection (HSPD) pixels 120. Further, for each HSPD pixel 120, grid structure 132 may include a half-shield (HS) 130 that covers approximately half of the associated HSPD pixel 120 for phase detection purposes. In some embodiments, grid structure 132 may include a metal, metal alloy, or another material that substantially reflects light.

Returning to FIG. 1A, in some embodiments, CFs 134 may be disposed over grid structure 132 and sensor dielectric layer 106. In some embodiments, each CF 134 may be disposed over a corresponding color pixel 122, and possibly a corresponding HSPD pixel 120, as described in detail below. Also, in some embodiments, each CF 134 extend through, or vertically span, grid structure 132 and may allow light associated with one of a number of colors (e.g., red, green, or blue) to pass therethrough to PD regions 104 associated with CF 134. As mentioned above, enhanced CF/MG layer 108 may include crosstalk reduction structure 109 that is level with or lateral to CFs 134 of enhanced CF/MG layer 108. FIGS. 1A and 1B particularly depict crosstalk reduction structure 109 as an additional color filter (e.g., as described below in greater detail with respect to FIG. 4). However, other crosstalk reduction structures (e.g., an anti-reflective coating over at least a portion of the grid structure, a variation in widths of segments of the grid structure, and so on) are also possible, as discussed below.

As illustrated in FIG. 1B, color pixels 122 may be arranged in a particular pattern (e.g., within a two-dimensional array) to facilitate accurate color imaging. Further, HSPD pixels 120 may be distributed in a periodic manner among color pixels 122. In some embodiments, HSPD pixels 120 may be disposed in pairs. For example, a first HSPD pixel 120 may correspond with a HS 130 covering a first (e.g., left-hand) PD region 104 of the two PD regions 104 associated with first HSPD pixel 120. Further, a second HSPD pixel 120 may correspond with a HS 130 covering a second (e.g., right-hand) PD region 104 of the two PD regions 104 associated with second HSPD pixel 120. However, other arrangements of color pixels 122 and HSPD pixels 120 other than that shown in FIG. 1B are also possible.

Returning to FIG. 1A, a lens layer 110 (e.g., including a plurality of lenses, such as microlenses) may be disposed over enhanced CF/MG layer 108. In some embodiments, each lens of lens layer 110 may be associated with a corresponding pixel (e.g., color pixel 122 or HSPD pixel 120), and thus positioned over the pair of PD regions 104 associated with that pixel. While each lens of lens layer 110 is presented as a microlens in the embodiments described in greater detail below, other types of lenses (e.g., Fresnel-type lenses) may be employed in other embodiments, but are not specifically discussed herein.

FIGS. 2A through 2F, FIGS. 3 through 8, and FIGS. 9A and 9B illustrate cross-sectional views of some embodiments of an IC device (e.g., IC device 100) employing a crosstalk reduction structure for half-shield PDAF, according to the present disclosure. In each of these embodiments, a substrate 102 includes a plurality of photodetectors (PDs) (e.g., photodiodes or the like) that include PD regions 104 that are formed (e.g., doped or implanted) in substrate 102. In some embodiments (e.g., in FIGS. 2A, 2B, 3-8, 9A, and 9B), PD regions 104 and their associated photodetectors are organized in pairs, with each pair being associated with either a color pixel 122 or an HSPD pixel 120. In other embodiments (e.g., in FIGS. 2C and 2D), each color pixel 122 includes a single PD region 104, while each HSPD pixel 120 includes two PD regions 104. In yet other embodiments (e.g., in FIGS. 2E and 2F), each color pixel 122 and HSPD pixel 120 includes a single PD region 104.

In some embodiments, a high-dielectric-constant (high-K) dielectric film 204 is disposed over substrate 102. Examples of high-K dielectric film 204 may include, but are not limited to, aluminum oxide (Al₂O₃), hafnium oxide (HfO₂), zirconium dioxide (ZrO₂), titanium dioxide (TiO₂), or the like. Further, a sensor dielectric layer 106 may be disposed over high-K dielectric film 204. As described above, sensor dielectric layer 106 may include, but is not limited to, silicon dioxide (SiO₂), another silicon oxide (SiOₓ), or another dielectric material.

In addition, between at least some adjacent PD regions 104 (e.g., between adjacent color pixels 122 or between a color pixel 122 and an HSPD pixel 120), a shallow trench isolation (STI) structure 202 may extend into a lower surface of substrate 102. In some embodiments, STI structure 202 may include a dielectric material, such as SiO₂, SiOₓ, or the like. Further, between each neighboring pair of PD regions 104, a backside deep trench isolation (BDTI) structure 210 may extend into an upper surface of substrate 102. BDTI structure 210, as depicted in FIG. 2A, may include multiple layers of materials. In some embodiments, BDTI structure 210 may include a core 214 that includes a light-reflective material that may include one or more metals or oxides. Surrounding core 214 may be a dielectric film 216. In some embodiments, dielectric film 216 may include, but is not limited to, an oxide (e.g., SiO₂, SiOₓ, or another oxide) or another dielectric material. In turn, covering dielectric film 216 may be a high-K dielectric film 218, which may include the same or similar material as high-K dielectric film 204, as described above.

Over sensor dielectric layer 106, a grid structure including grid segments 133, as described above in connection with FIGS. 1A and 1B, is disposed. Grid segments 133, in a plan view of IC device 100, provide an opening for each color pixel 122 and HSPD pixel 120. The grid structure may also include half-shields 130, each of which cover one PD region 104 of each photodetector pair of a corresponding HSPD pixel 120. Further, over the grid structure and sensor dielectric layer 106, for each color pixel 122, a CF 134 is disposed to cover the photodetector pair associated with color pixel 122. Together, CFs 134 and the grid structure 132 (e.g., grid structure 132 of FIGS. 1A and 1B) may be included in an enhanced CF/MG layer 108. In some embodiments, each CF 134 may be a dielectric material that filters one or more wavelength bands of light to allow a particular wavelength band (e.g., a band that includes red, green, or blue) to pass therethrough. Also, in some embodiments, each CF 134 may include a pigment, dye, or other light-transmissive material that filters one or more wavelength bands of light.

Over CFs 134 and sensor dielectric layer 106, a lens layer 110 including a plurality of microlenses 220 may be disposed. Each microlens 220 may correspond with one color pixel 122 or HSPD pixel 120. For example, in some embodiments, each microlens 220 may direct at least some light through a corresponding CF 134 (if present), sensor dielectric layer 106, high-K dielectric film 204, and substrate 102 into one or both PD regions 104 thereunder, depending on the possible presence of a half-shield 130. In some embodiments, microlenses 220 may be fabricated from a polymer, an oxide (e.g., SiO₂), or other substantially transparent material.

In addition, in some embodiments, an anti-reflective coating (ARC) 222 may be disposed over microlenses 220. In some embodiments, ARC 222 may be fabricated using titanium nitride (TiN), silicon nitride (SiN), silicon oxynitride (SiON), tantalum pentoxide (Ta₂O₅), and/or another anti-reflective material that allows light to pass therethrough.

In FIGS. 2A through 2F, FIGS. 3 through 8, and FIGS. 9A and 9B, the various components of color pixels 122 and HSPD pixel 120 are not stacked strictly vertically, but are instead shown to be skewed. More specifically, microlenses 220, CFs 134, and/or the grid structure (including grid segments 133 and half-shield 130) are laterally offset from PD regions 104 associated with each color pixel 122 and HSPD pixel 120. As described above, in such cases, such lateral offsets are present to adapt the associated pixels to a chief ray angle that is non-zero, such as for pixels that are not centrally located in a pixel array provided by IC device 100. In such examples, the potential for crosstalk from HSPD pixel 120 (e.g., by way of reflection of half-shield 130) to a neighboring color pixel 122 may be increased without the incorporation of a crosstalk reduction structure employed in enhanced CF/MG layer 108.

FIGS. 2A, FIGS. 3 through 8, and FIGS. 9A and 9B address particular embodiments of IC device 100 in which each of color pixels 122 and HSPD pixels 120 correspond with two photodetectors and a same size microlens 220 and in which reflection from HS 130 is directed toward the adjacent color pixel 122 farther away from HS 130. However, other embodiments are also possible. For example, as shown in FIGS. 2B, 2D, and 2F, reflection from HS 130 is directed toward the adjacent color pixel 122 closer to HS 130. Also, in some embodiments (e.g., FIGS. 2E and 2F), each color pixel 122 and HSPD pixel 120 may correspond with a single PD region 104 and associated photodetector. In other embodiments (e.g., FIGS. 2C and 2D), a single PD region 104 is associated with each color pixel 122, while two PD regions 104 are associated with each HSPD pixel 120. In such embodiments, microlenses 220 corresponding to HSs 130 may be larger than microlenses 220 corresponding to color pixels 122. In yet other embodiments, more than two PD regions and associated photodetectors may be associated with each color pixel 122 and HSPD pixel 120. Other configurations for IC device 100 that are compatible with the various crosstalk reduction structure embodiments of FIGS. 2A through 2F, FIGS. 3 through 8, and FIGS. 9A and 9B are also possible.

FIGS. 2A through 2F illustrate cross-sectional views of some embodiments of IC devices 100A1, 100A2, 100A3, 100A4, 100A5, and 100A6, respectively. IC devices 100A1, 100A2, 100A3, 100A4, 100A5, and 100A6 each include an additional color filter 234A, 234B, 234C, 234D, 234E, and 234F, respectively, employed as a crosstalk reduction structure within an enhanced CF/MG layer 108A1, 108A2, 108A3, 108A4, 108A5, and 108A6, respectively. More particularly, additional color filter 234A through 234F may have the same filter spectrum (e.g., filter the same one or more wavelength bands) as color filter 134 of an adjacent color pixel 122 (e.g., color pixel 122 to the left of HSPD pixel 120 in FIGS. 2A through 2F). In some embodiments, additional color filter 234A through 234F may not extend laterally beyond the footprint of HS 130, as depicted in FIGS. 2A through 2F.

In some embodiments, as indicated by the dashed arrows in FIGS. 2A through 2F, light entering microlens 220 of HSPD pixel 120 may be filtered by additional color filter 234A through 234F, thus reducing the amount of light encountering HS 130. HS 130, in turn, may reflect that light back to microlens 220 of adjacent color pixel 122, which may reflect the filtered light by total internal reflection (TIR) toward color filter 134 of adjacent color pixel 122. Color filter 134 may then further reduce the amount of light that may ultimately reach one of PD regions 104 of adjacent color pixel 122. Overall, the inclusion of additional color filter 234A through 234F may reduce potential crosstalk from HSPD pixel 120 to adjacent color pixel 122.

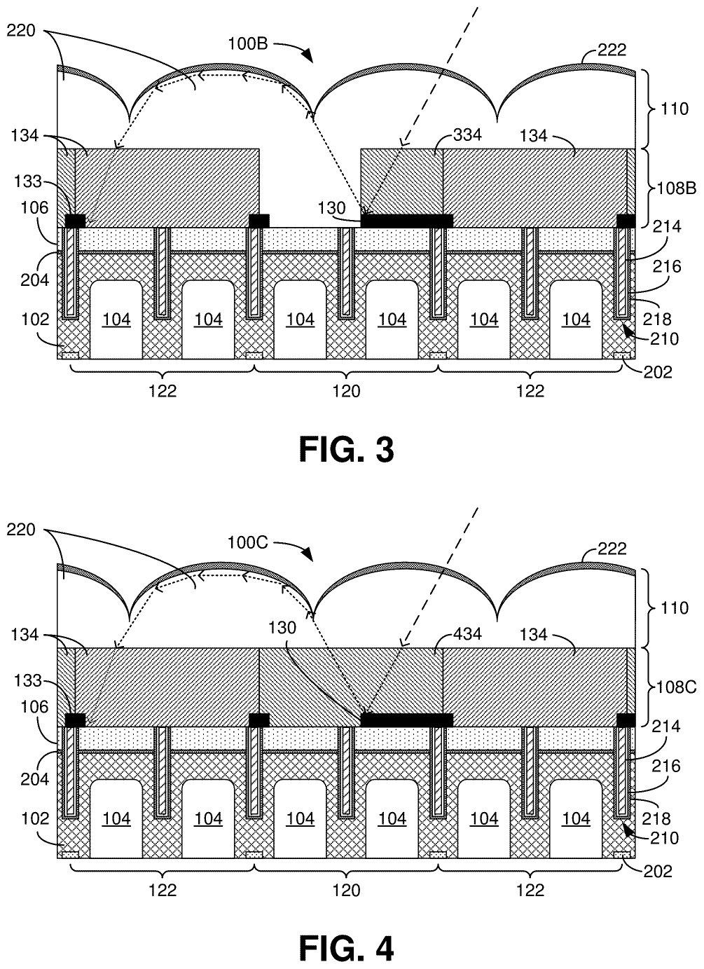

FIGS. 3 through 8 and FIGS. 9A and 9B employ other crosstalk reduction structures that employ the dual-PD pixel structure and right-sided half-shield configuration of FIG. 2A. However, each crosstalk reduction structure of FIGS. 3 through 8 and FIGS. 9A and 9B may employ the pixel structures and half-shield configurations of FIGS. 2B through 2F in other embodiments.

More specifically, FIG. 3 illustrates a cross-sectional view of some embodiments of an IC device 100B including an additional color filter 334 employed as a crosstalk reduction structure within an enhanced CF/MG layer 108B. In contrast to FIGS. 2A through 2F, additional color filter 334 may have a different filter spectrum (e.g., filter a different one or more wavelength bands) from that of color filter 134 of an adjacent color pixel 122 (e.g., color pixel 122 to the left of HSPD pixel 120 in FIG. 2). In some embodiments, additional color filter 334 may not extend laterally beyond the footprint of HS 130, as depicted in FIG. 3.

In some embodiments, as indicated by the dashed arrows in FIG. 3, the light entering microlens 220 of HSPD pixel 120 may be filtered by additional color filter 334, thus reducing the amount of light encountering HS 130. HS 130, in turn, may reflect that light back to microlens 220 of adjacent color pixel 122, which may reflect the filtered light by TIR toward color filter 134 of adjacent color pixel 122. Color filter 134 may then further reduce the amount of light that may ultimately reach one of PD regions 104 of adjacent color pixel 122, particularly because the wavelength bands filtered by color filter 134 may be different from those filtered by additional color filter 334, thus substantially reducing potential crosstalk from HSPD pixel 120 to adjacent color pixel 122.

FIG. 4 illustrates a cross-sectional view of some embodiments of an IC device 100C including an additional color filter 434 employed as a crosstalk reduction structure within an enhanced CF/MG layer 108C. More specifically, additional color filter 434 extends laterally beyond the footprint of HS 130. For example, additional color filter 434 may extend from color filter 134 of adjacent color pixel 122 (e.g., to the left of HSPD pixel 120, as depicted in FIG. 4) to color filter 134 of another adjacent color pixel 122 (e.g., to the right of HSPD pixel 120, as depicted in FIG. 4). In some embodiments, a filter spectrum of additional color filter 434 may be different from that of color filter 134 of adjacent color pixel 122 (e.g., as shown in FIG. 3). In other embodiments, the filter spectrum of additional color filter 434 may be the same as that of color filter 134 of adjacent color pixel 122 (e.g., as shown in FIGS. 2A through 2F).

In some embodiments, as indicated by the dashed arrows in FIG. 4, additional color filter 434 may filter a significant amount of light due to the light passing through additional color filter 334 material both before and after reflection by HS 130, thus reducing potential crosstalk from HSPD pixel 120 to adjacent color pixel 122 to a significant degree.

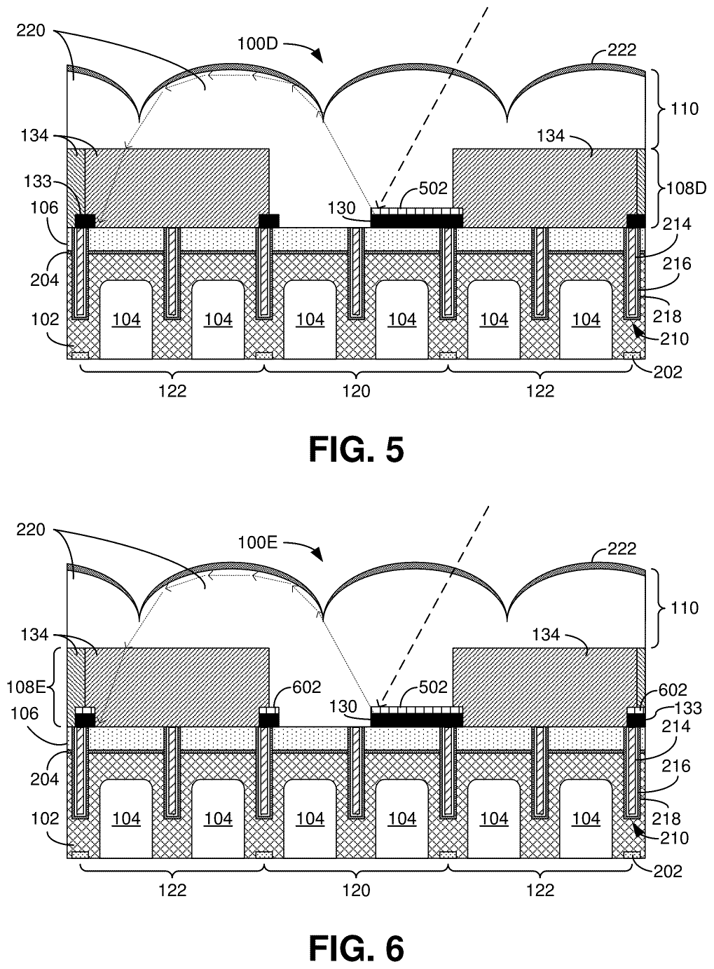

FIG. 5 illustrates a cross-sectional view of some embodiments of an IC device 100D including an anti-reflective coating (ARC) 502 employed as a crosstalk reduction structure within an enhanced CF/MG layer 108D. ARC 502 may be disposed directly atop HS 130 and may extend laterally over an entirety of HS 130. In some embodiments, ARC 502 may reduce the amount of light reflected from an upper surface of HS 130 toward adjacent color pixel 122, as indicated by way of the dashed arrows shown in FIG. 5. Also, in some embodiments, ARC 502 may include TiN, SiN, SiON, Ta₂O₅, and/or another anti-reflective material that reduces the amount of light reflected toward adjacent color pixel 122. Further, in some embodiments, ARC 502 may be provided in addition to any of additional color filter 234A of FIG. 2A, additional color filter 334 of FIG. 3, or additional color filter 434 of FIG. 4.

FIG. 6 illustrates a cross-sectional view of some embodiments of an IC device 100E including an anti-reflective coating (ARC) 502 and an ARC 602 employed as a crosstalk reduction structure within an enhanced CF/MG layer 108E. In some embodiments, ARC 602 may be placed atop each of grid segments 133 in addition to ARC 502 lying atop HS 130. Also, in some embodiments, ARC 602 may provide further reduction of reflected light from an upper surface of grid segments 133 in addition to that provided by ARC 502, thus reducing crosstalk from HSPD pixel 120 to adjacent color pixel 122. Further, in some embodiments, ARC 602 may include TiN, SiN, SiON, Ta₂O₅, and/or another anti-reflective material that reduces the amount of light reflected from grid segments 133. Further, in some embodiments, ARCs 502 and 602 may be provided in addition to any of additional color filter 234A of FIG. 2A, additional color filter 334 of FIG. 3, or additional color filter 434 of FIG. 4.

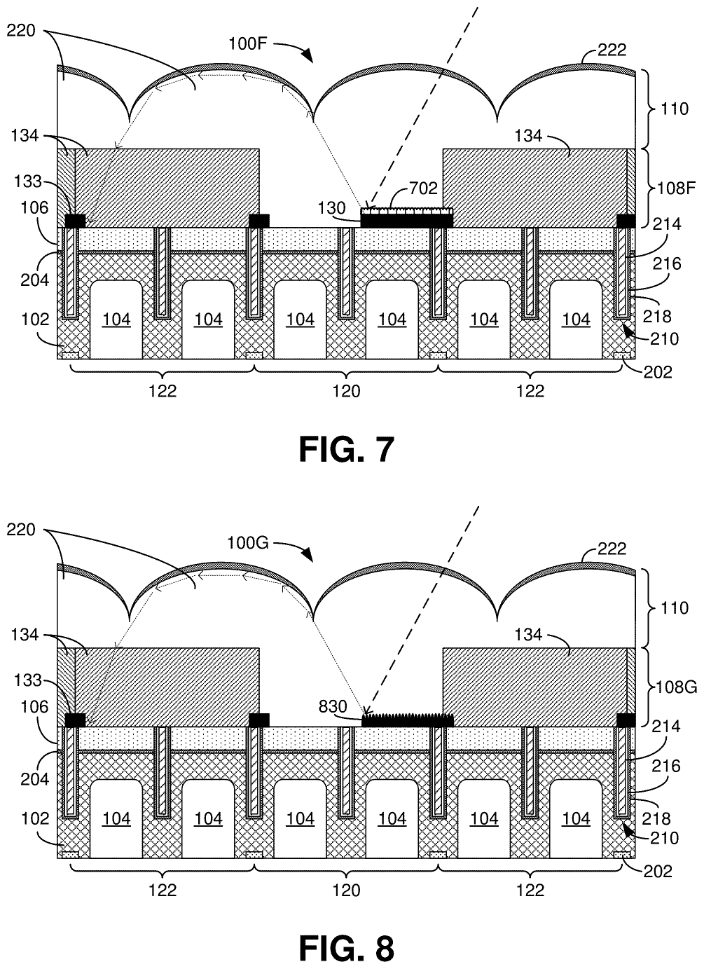

FIG. 7 illustrates a cross-sectional view of some embodiments of an IC device 100F including an anti-reflective coating (ARC) 702 employed as a crosstalk reduction structure within an enhanced CF/MG layer 108F. In some embodiments, ARC 702 may be disposed atop HS 130. In addition, an upper surface of ARC 702 may be rough or otherwise irregular to further reduce light reflection therefrom. In some embodiments, the upper surface of ARC 702 may be roughened by way of acid etching, other types of etching, or other processes by which material may be added or removed. Further, in some embodiments, ARC 702 may include TiN, SiN, SiON, Ta₂O₅, and/or another anti-reflective material that reduces the amount of light reflected from HS 130. Further, in some embodiments, an ARC with a roughened upper surface may also be disposed over grid segments 133. Moreover, in some embodiments, ARC 702 may be provided in addition to any of additional color filter 234A of FIG. 2A, additional color filter 334 of FIG. 3, or additional color filter 434 of FIG. 4.

FIG. 8 illustrates a cross-sectional view of some embodiments of an IC device 100G including an HS 830 within HSPD pixel 120 that has a roughened or otherwise irregular upper surface employed as a crosstalk reduction structure within an enhanced CF/MG layer 108G to reduce light reflection therefrom. In some embodiments, the upper surface of HS 830 may be roughened by way of acid etching, other types of etching, or other processes by which material may be added or removed. Further, in some embodiments, an upper surface of grid segments 133 may be similarly roughened to further reduce reflections thereby. Moreover, in some embodiments, HS 830 may be provided in addition to any of additional color filter 234A of FIGS. 2A, additional color filter 334 of FIG. 3, or additional color filter 434 of FIG. 4.

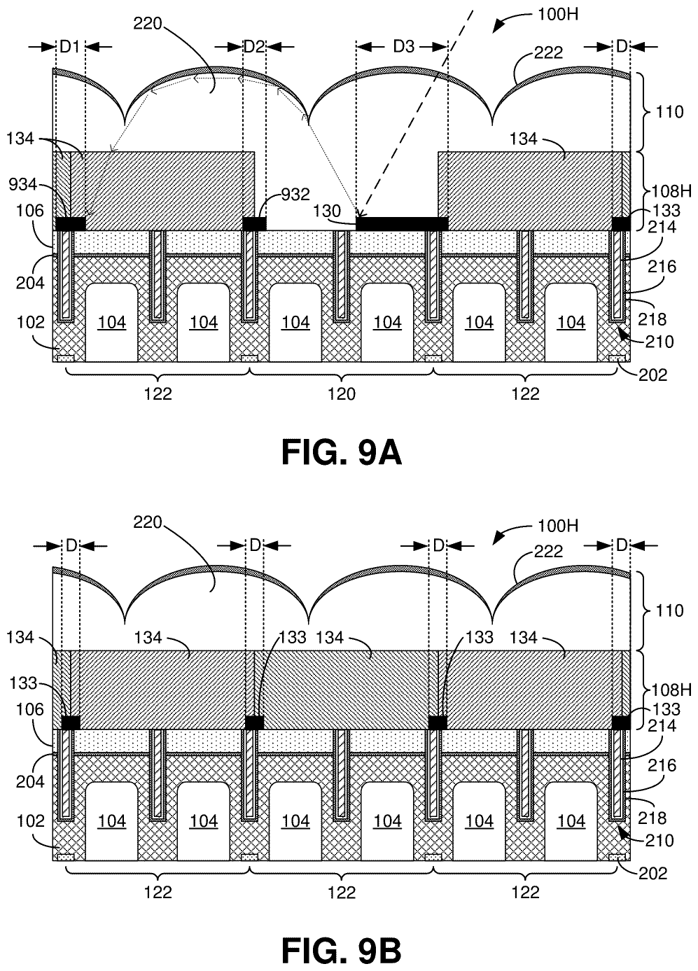

FIGS. 9A and 9B illustrate cross-sectional views of some embodiments of an IC device 100H including a grid structure with grid segments of varying widths employed as a crosstalk reduction structure within an enhanced CF/MG layer 108H. More specifically, FIG. 9A provides a cross-sectional view of HSPD pixel 120 and adjacent color pixels 122. FIG. 9B provides a cross-sectional view of color pixels 122 that are not adjacent HSPD pixel 120.

In some embodiments, color pixels 122 not in the vicinity of HSPD pixel 120 (e.g., as shown in FIG. 9B) may correspond with grid segments 133 having a width D. Further, as depicted in FIG. 9A, a color pixel 122 adjacent HSPD pixel 120 on a side closest HS 130 (e.g., color pixel 122 to the right of HSPD pixel 120 in FIG. 9A) may also correspond with a grid segment 133 with a width D. As also shown in FIG. 9A, between HSPD pixel 120 and adjacent color pixel 122 farther from HS 130 of HSPD pixel 120 (e.g., color pixel 122 to the left of HSPD pixel 120) may be a grid segment 932 having a width D2 greater than D. Moreover, a grid segment 934 associated with the same adjacent color pixel 122, but positioned farther from HSPD pixel 120, may have a width D1 greater than D or D2. In addition, HS 130 of HSPD pixel 120 may have a width D3 greater than D, D1, or D2.

In some embodiments, as depicted in FIG. 9A, D3 may be approximately half the width of HSPD pixel 120, which may be approximately the distance from a BDTI structure 210 to an adjacent BDTI structure 210. Further, in some embodiments, D1 may be in the range of 1.5 D to 2.0 D. Also, in some embodiments, D2 may be in the range of 1.1 D to 1.5 D.

The widths D2 and D1 of grid segments 932 and 934, respectively, may prevent some light reflected by HS 130 of HSPD pixel 120 from reaching PD regions 104 of adjacent color pixel 122 while allowing non-adjacent color pixels 122 corresponding with grid segments 133 of width D more extensive light reception.

Further, in some embodiments, embodiments of FIGS. 9A and 9B may be combined with other embodiments described above (e.g., embodiments associated with one or more of FIG. 2A and FIGS. 3 through 8) to further reduce possible crosstalk from HSPD pixel 120 to adjacent color pixel 122.

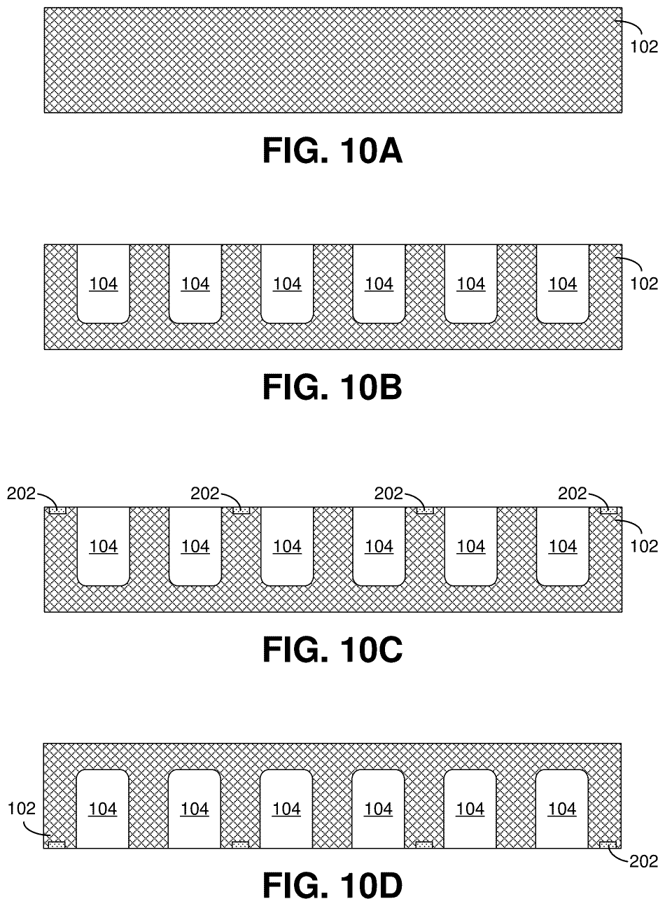

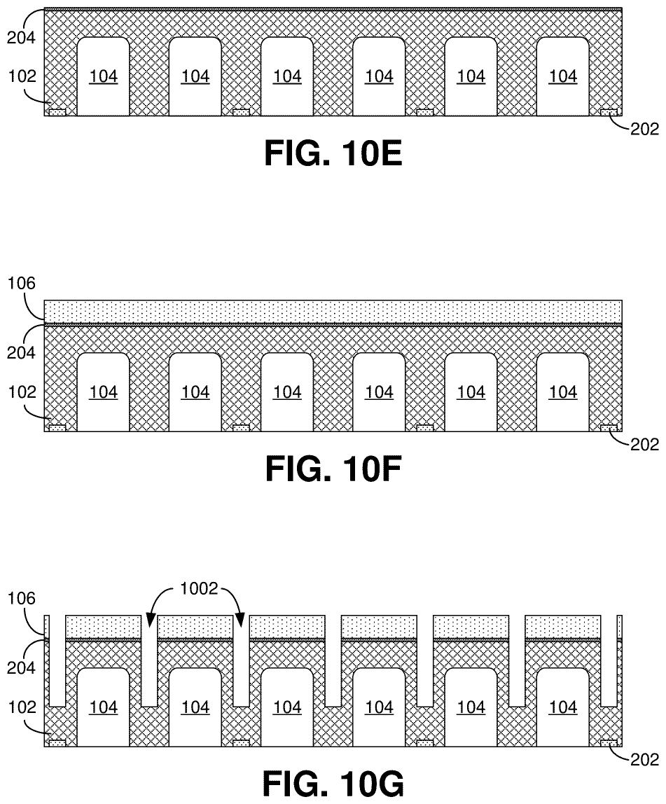

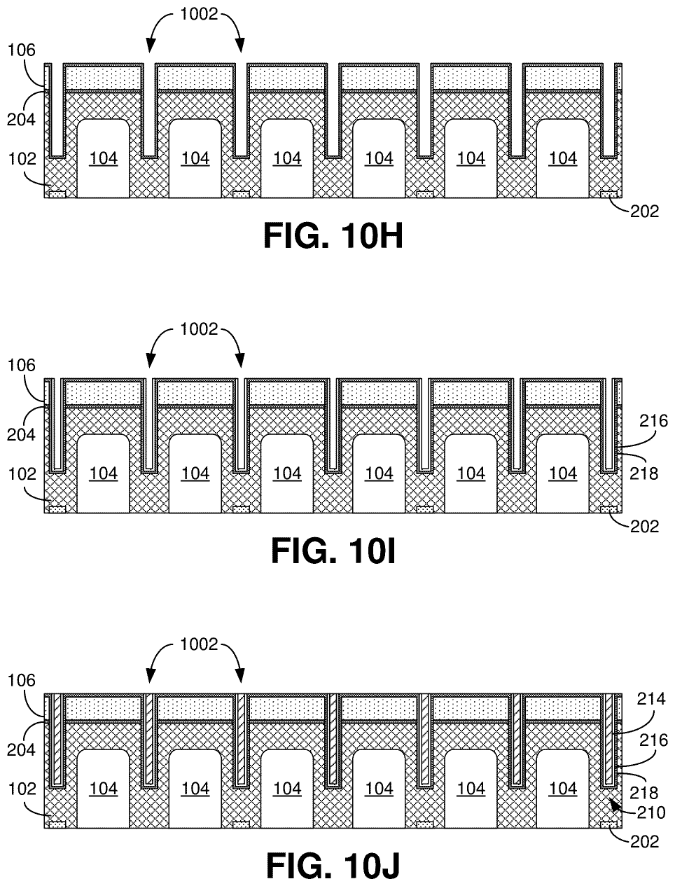

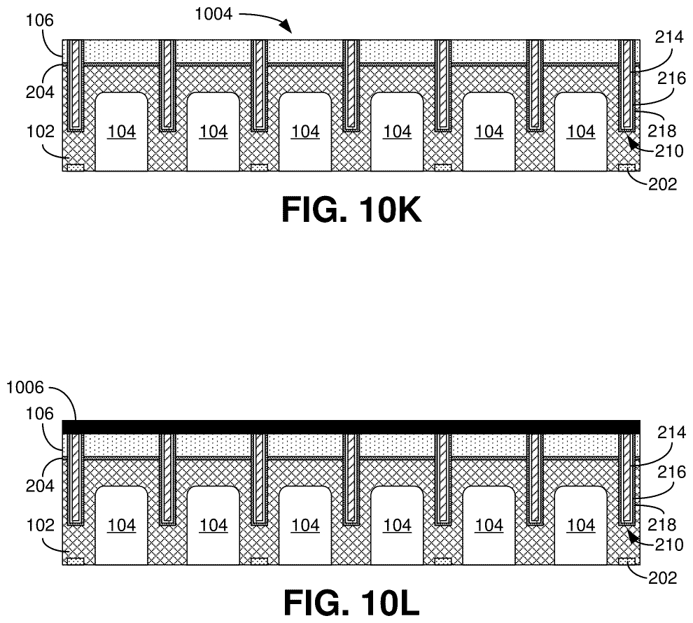

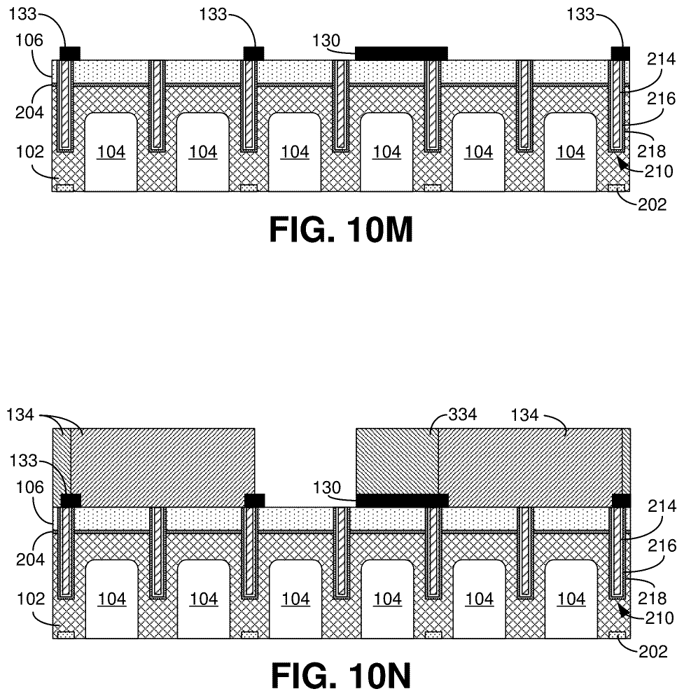

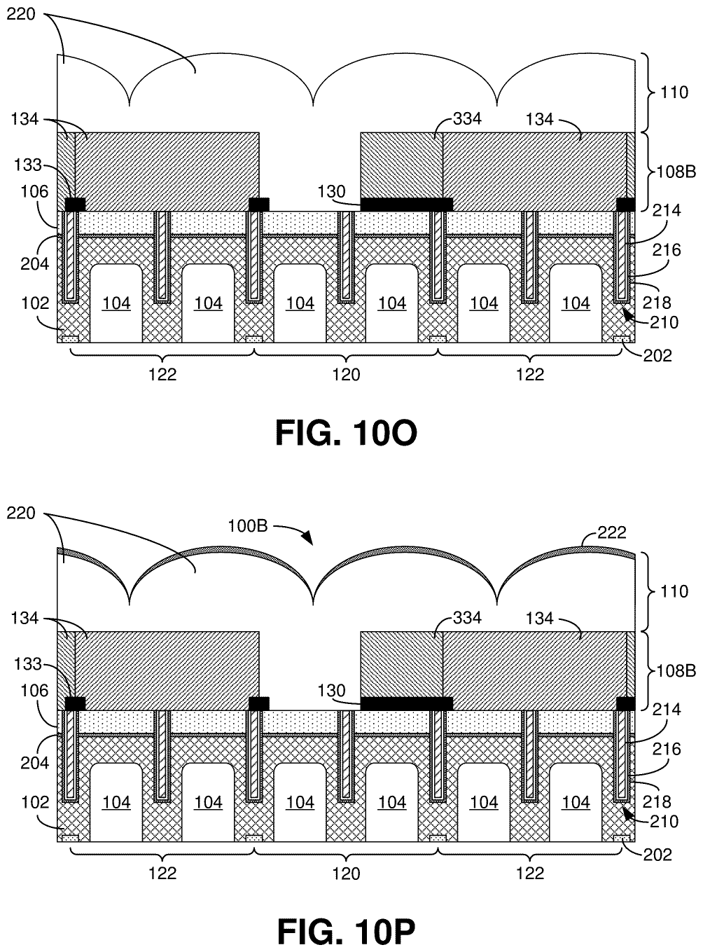

FIGS. 10A through 10P illustrate cross-sectional views of some embodiments of an IC device employing a crosstalk reduction structure (e.g., IC device 100B of FIG. 3) at various stages of manufacture, according to the present disclosure. Although FIGS. 10A through 10P are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 10A illustrates a substrate 102 (e.g., a semiconductor substrate, such as a silicon substrate). In some embodiments, substrate 102 may serve as a substrate for a backside portion of IC device 100B, including a sensor dielectric layer 106, a grid structure 132, and so on, as depicted for IC device 100 in FIG. 1A. In addition, substrate 102 may also serve as a substrate for a frontside portion of IC device 100B, such as circuit dielectric layer 112 and associated sensor circuit 114 of FIG. 1A, the presence of which is not explicitly depicted in FIGS. 10A through 10P to simplify the following discussion.

FIG. 10B illustrates the forming (e.g., implantation, doping, or the like) of PD regions 104 via a frontside surface of substrate 102 to form corresponding photodetectors (e.g., PN photodiodes, PIN photodiodes, or the like) in conjunction with surrounding areas of substrate 102. In some embodiments, substrate 102 may be a p-type substrate and PD regions 104 may be n-doped PD regions. In other embodiments, PD regions 104 may be employed to form other types of photodetectors in conjunction with substrate 102.

FIG. 10C illustrates the forming (e.g., etching and deposition) of STI structures 202 at the frontside surface of substrate 102. In some embodiments, STI structures 202 may be positioned between every pair of PD regions 104, thus organizing PD regions 104 into photodetector pairs, where each pair forms a dual-PD pixel. In some embodiments, an STI structure 202 may include silicon oxide (SiOₓ) (e.g., silicon oxide (SiO₂)) or another oxide or dielectric material. In some embodiments, STI structures 202 may assist in reducing current leakage between consecutive photodetector pairs.

FIG. 10D illustrates the inversion (e.g., flipping) of substrate 102 such that a backside surface of substrate 102 opposite the frontside surface is accessible to facilitate subsequent processing as described below with respect to FIGS. 10E through 10N.

FIG. 10E illustrates the forming (e.g., deposition) of a high-K dielectric film 204 on an upper (e.g., backside) surface of substrate 102. As mentioned above, in some embodiments, high-K dielectric film 204 may include at least one high-K dielectric material, including, but not limited to, Al₂O₃, HfO₂, ZrO₂, TiO₂, or the like.

FIG. 10F illustrates the forming (e.g., deposition) of a sensor dielectric layer 106 on high-K dielectric film 204. In some embodiments, sensor dielectric layer 106 may include, but is not limited to, silicon dioxide (SiO₂), another silicon oxide (SiOₓ), or another dielectric material. Thereafter, in some embodiments, an upper surface of sensor dielectric layer 106 may be planarized (e.g., via chemical-mechanical planarization (CMP)).

FIG. 10G illustrates the forming (e.g., photolithography and associated etching) of trenches 1002 through sensor dielectric layer 106 and high-K dielectric film 204, and into substrate 102. In some embodiments, trenches 1002 may extend well into (e.g., two-thirds, three-quarters, etc.) substrate 102. Also, in some embodiments, trench 1002 may be formed between a PD region 104 and an adjacent PD region 104.

FIG. 10H illustrates the forming (e.g., conformal deposition) of an additional high-K dielectric film 218. In some embodiments, such deposition may allow high-K dielectric film 218 to cover an upper surface of sensor dielectric layer 106 and the sidewalls of each trench 1002.

FIG. 10I illustrates the forming (e.g., conformal deposition) of a dielectric film 216 within each trench 1002 while leaving a void within each trench 1002. In some embodiments, dielectric film 216 may include, but is not limited to, an oxide (e.g., SiO₂, SiOₓ, or another oxide) or another dielectric material.

FIG. 10J illustrates the forming (e.g., deposition) of a core 214 in the remaining void of each trench 1002. In some embodiments, core 214 may include a light-reflective material, such as one or more metals or oxides, resulting in BDTI structures 210. Accordingly, BDTI structures 210 may help provide at least some optical isolation between PD regions 104.

FIG. 10K illustrates the removal (e.g., blanket etching) of additional high-K dielectric film 218 (and possibly light-reflective material remaining from the forming of core 214) from sensor dielectric layer 106 to expose upper surface 1004 of sensor dielectric layer 106. In some embodiments, such etching may result in an upper surface of dielectric film 216 being slightly lower than that of core 214 and/or additional high-K dielectric film 218.

FIG. 10L illustrates the forming (e.g., deposition) of a metal layer 1006 (e.g., copper (Cu) or another metal or metal alloy) on sensor dielectric layer 106 and BDTI structures 210. In other embodiments, a light-reflective material other than a metal or metal allow may be employed in lieu of metal layer 1006.

FIG. 10M illustrates the selective removal (e.g., photolithography and etching) of portions of metal layer 1006 to form a grid structure (e.g., grid structure 132 of FIGS. 1A and 1B) that includes grid segments 133 and half shields (HSs) 130, as described above. In some embodiments, HS 130 may cover approximately an entire PD region 104, or approximately half of a pixel (e.g., HSPD pixel 120 of FIG. 3).

FIG. 10N illustrates the forming (e.g., deposition) of color filters 134 and additional color filter 334. In some embodiments, each color filter 134 may be associated with a corresponding color pixel (e.g., color pixel 122 of FIG. 3), while additional color filter 334 may be associated with a corresponding HSPD pixel (e.g., HSPD pixel 120 of FIG. 3). As described above, in some embodiments, each CF 134 and additional CF 134 may allow light associated with a particular color (e.g., red, green, or blue) to pass therethrough, thus filtering other colors. In some embodiments, the forming of color filters 134 and additional color filter 334 may include, for each type or color of color filter 134 and 334, applying a color composition layer, selectively patterning (e.g., exposing to ultraviolet (UV) light) the color composition layer, and removing unexposed areas of the color composition layer to form a pattern of CFs 134 and 334 having the desired color.

Further, in some embodiments, additional color filter 334 covers HS 130 to provide a crosstalk reduction structure, as shown in FIG. 3. In other embodiments, as described above, other types of crosstalk reduction structures, such as those associated with other color filters or the grid structure (e.g., as shown in FIGS. 2A, 4-8, 9A, and 9B) may be formed in lieu of, or in addition to, additional color filter 334.

FIG. 10O illustrates the forming (e.g., deposition, patterning, and reflowing) of a plurality of microlenses 220 for a lens layer 110. Each microlens 220 may be configured to focus light towards PD regions 104 for a corresponding color pixel 122 or HSPD pixel 120. In some embodiments, the forming of microlenses 220 may include forming a photosensitive layer of substantially transparent material (e.g., a polymer, an oxide (e.g., SiO₂), or other substantially transparent material), patterning the photosensitive layer, and then reflowing the patterned photosensitive layer (e.g., at some predetermined temperature) to form microlenses 220.

FIG. 10P illustrates the forming (e.g., deposition) of an ARC 222 on microlenses 220. In some embodiments, ARC 222 may include, but is not be limited to, TiN, SiN, SiON, Ta₂O₅, and/or other another anti-reflective material that allows light to pass therethrough.

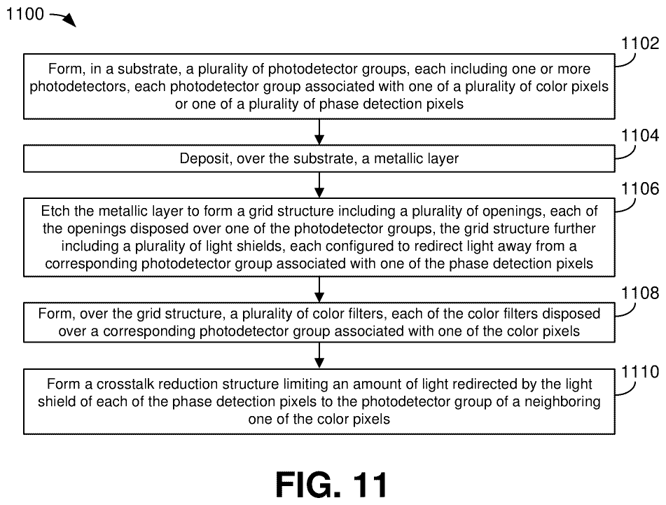

FIG. 11 illustrates a block diagram of some embodiments of a methodology 1100 of forming an IC device (e.g., IC device 100B of FIG. 3) employing a crosstalk reduction structure for half-shield PDAF, according to the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At Act 1102, a plurality of photodetector groups (e.g., photodetectors formed using PD regions 104 of FIG. 3) are formed (doped or implanted) in a substrate (e.g., substrate 102 of FIG. 3). Each photodetector group includes one or more photodetectors. Also, each photodetector group is associated with one of a plurality of color pixels (e.g., color pixels 122 of FIG. 3) or one of a plurality of phase detection pixels (e.g., HSPD pixels 120 of FIG. 3). In some embodiments, the substrate may be a semiconductor substrate, such as a silicon substrate. FIGS. 10A and 10B illustrate cross-sectional views of some embodiments corresponding to Act 1102.

At Act 1104, a metallic layer (e.g., metallic layer 1006 of FIG. 10L) is formed over the substrate. FIG. 10L illustrates a cross-sectional view of some embodiments corresponding to Act 1104.

At Act 1106, the metallic layer is etched to form a grid structure (e.g., grid structure 132 of FIGS. 1A and 1B) including a plurality of openings (e.g., openings 131 of FIG. 1B). Each of the openings is disposed over one of the photodetector groups. The grid structure further includes a plurality of light shields (e.g., HS 130 of FIGS. 1A, 1B, and 3). Each light shield is configured to redirect light away from a corresponding photodetector group associated with one of the phase detection pixels. FIG. 10M illustrates a cross-sectional view of some embodiments corresponding to Act 1106.

At Act 1108, a plurality of color filters (e.g., CFs 134 of FIG. 3) is formed over the grid structure. Each color filter is disposed over a corresponding photodetector group associated with one of the color pixels. FIG. 10N illustrates a cross-sectional view of some embodiments corresponding to Act 1108.

At Act 1110, a crosstalk reduction structure (e.g., additional color filters 234A through 234F of FIGS. 2A through 2F, additional color filter 334 of FIG. 3, additional color filter 434 of FIG. 4, ARC 502 of FIG. 5, ARCs 502 and 602 of FIG. 6, ARC 702 of FIG. 7, HS 830 of FIG. 8, grid segments 932 and 934 of FIG. 9A, and combinations thereof) is formed. The structure limits an amount of light redirected by the light shield of each of the phase detection pixels to the photodetector group of a neighboring one of the color pixels. FIG. 10N illustrates cross-sectional views of some embodiments corresponding to Act 1110 (e.g., relating to additional color filter 334 of FIG. 3).

In some embodiments, the present disclosure provides an IC device, including: a substrate including a plurality of first photodetector groups respectively associated with a plurality of color pixels and a plurality of second photodetector groups respectively associated with a plurality of phase detection pixels, wherein each of the first photodetector groups and the second photodetector groups includes one or more photodetectors; a grid structure over the substrate, wherein the grid structure includes a plurality of light shields, each configured to redirect light away from a corresponding one of the second photodetector groups; a plurality of color filters over the substrate and each vertically spanning the grid structure at a corresponding one of the first photodetector groups; and a crosstalk reduction structure lateral to the color filters and limits an amount of the light redirected by the light shield of each of the phase detection pixels to the first photodetector group of a neighboring one of the color pixels. In some embodiments, the crosstalk reduction structure includes a plurality of additional color filters, each atop a corresponding one of the light shields. In some embodiments, each of the additional color filters lies entirely within a footprint of the corresponding one of the light shields in a plan view of the IC device. In some embodiments, each of the additional color filters extends through the grid structure at the corresponding one of the light shields. In some embodiments, each of the additional color filters has a same filter spectrum as a filter spectrum of a color filter corresponding to a neighboring one of the color pixels. In some embodiments, each of the additional color filters has a different filter spectrum as a filter spectrum of a color filter corresponding to a neighboring one of the color pixels. In some embodiments, the crosstalk reduction structure includes an anti-reflective coating disposed on each of the light shields. In some embodiments, the anti-reflective coating includes a non-planar upper surface facing away from the substrate. In some embodiments, the crosstalk reduction structure includes an anti-reflective coating disposed on an entirety of the grid structure. In some embodiments, the crosstalk reduction structure includes a non-planar upper surface of each of the light shields, the non-planar upper surface facing away from the substrate. In some embodiments, the crosstalk reduction structure includes a plurality of grid segments of the grid structure, which increase in width away from the phase detection pixels. In some embodiments, the grid segments include: a first grid segment between one of the phase detection pixels and one of the color pixels neighboring the one of the phase detection pixels, wherein the first grid segment has a first width; and a second grid segment between the one of the color pixels and an adjacent one of the color pixels, wherein the second grid segment has a second width greater than the first width. In some embodiments, the grid segments further include: a third grid segment disposed on an opposite side of the one of the phase detection pixels as the first grid segment, wherein the third grid segment has a third width less than the second width.

In some embodiments, the present disclosure provides another IC device, including: a substrate including a first at least one photodetector and a second at least one photodetector adjacent the first at least one photodetector, the first at least one photodetector associated with a phase detection pixel, and the second at least one photodetector associated with a color pixel; a grid structure over the substrate and including: a light shield over a first portion of the first at least one photodetector; a first opening over a second portion of the first at least one photodetector different from the first portion; and a second opening over the second at least one photodetector; a color filter over the second at least one photodetector, in the second opening; and a crosstalk reduction structure that is lateral to the color filter and configured to limit light redirected by the light shield to the second at least one photodetector. In some embodiments, the crosstalk reduction structure includes an additional color filter over the light shield. In some embodiments, the crosstalk reduction structure includes an anti-reflective coating on the light shield. In some embodiments, the crosstalk reduction structure includes a non-planar upper surface of the light shield, the non-planar upper surface facing away from the substrate.

In some embodiments, the present disclosure provides a method, including: forming, in a substrate, a plurality of photodetector groups, each including one or more photodetectors, each photodetector group associated with one of a plurality of color pixels or one of a plurality of phase detection pixels; depositing, over the substrate, a metallic layer; etching the metallic layer to form a grid structure including a plurality of openings, each of the openings disposed over one of the photodetector groups, and further including a plurality of light shields, each configured to redirect light away from a corresponding photodetector group associated with one of the phase detection pixels; forming, over the grid structure, a plurality of color filters, each of the color filters disposed over a corresponding photodetector group associated with one of the color pixels; and forming a crosstalk reduction structure that is lateral to the plurality of color filters and limits an amount of the light redirected by the light shield of each of the phase detection pixels to the photodetector group of a neighboring one of the color pixels. In some embodiments, the crosstalk reduction structure includes a plurality of additional color filters, each disposed over a corresponding one of the light shields. In some embodiments, the crosstalk reduction structure includes an anti-reflective coating disposed on each of the light shields.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate comprising a first at least one photodetector and a second at least one photodetector adjacent the first at least one photodetector, the first at least one photodetector associated with a phase detection pixel, and the second at least one photodetector associated with a color pixel;
a grid structure over the substrate and comprising:
a light shield over a first portion of the first at least one photodetector;
a first opening over a second portion of the first at least one photodetector;
a second opening over the second at least one photodetector; and
a plurality of grid segments laterally surrounding the first opening and the second opening;
a color filter over the second at least one photodetector, in the second opening; and
an anti-reflective structure on the light shield.

2. The IC device of claim 1, wherein the anti-reflective structure comprises an anti-reflective coating disposed on the light shield.

3. The IC device of claim 2, wherein the anti-reflective coating includes a non-planar upper side.

4. The IC device of claim 2, wherein the anti-reflective coating is further disposed on an entirety of the grid structure.

5. The IC device of claim 1, wherein the anti-reflective structure comprises a non-planar upper side of the light shield.

6. A method of fabricating an integrated circuit (IC) device, the method comprising:
forming, in a substrate, a first at least one photodetector and a second at least one photodetector adjacent the first at least one photodetector, the first at least one photodetector associated with a phase detection pixel, and the second at least one photodetector associated with a color pixel;
depositing, over the substrate, a metallic layer;
etching the metallic layer to form a grid structure comprising:
a light shield over a first portion of the first at least one photodetector;
a first opening over a second portion of the first at least one photodetector;
a second opening over the second at least one photodetector;
a first grid segment laterally separating the first opening and the second opening; and
a second grid segment laterally separating the second opening and an additional opening adjacent the second opening opposite the first opening, a width of the first grid segment being less than a width of the second grid segment; and
forming, over the grid structure, a color filter over the second at least one photodetector, in the second opening.

7. The method of claim 6, the light shield having a width greater than the width of the first grid segment and the width of the second grid segment.

8. The method of claim 6, the grid structure further comprising:
a third grid segment disposed on an opposite side of the phase detection pixel from the first grid segment, the third grid segment having a width less than the width of the first grid segment.

9. The method of claim 8, the width of the first grid segment being in a range of 1.1 to 1.5 times the width of the third grid segment.

10. A method of fabricating an integrated circuit (IC) device, the method comprising:
forming, in a substrate, a first at least one photodetector and a second at least one photodetector adjacent the first at least one photodetector, the first at least one photodetector associated with a phase detection pixel, and the second at least one photodetector associated with a color pixel;
depositing, over the substrate, a metallic layer;
etching the metallic layer to form a grid structure comprising:
a light shield over a first portion of the first at least one photodetector;
a first opening over a second portion of the first at least one photodetector; and
a second opening over the second at least one photodetector; and
forming, over the grid structure:
a first color filter over the light shield; and
a second color filter over the second at least one photodetector, in the second opening.

11. The method of claim 10, the first color filter lying entirely within a footprint of the light shield in a plan view of the IC device.

12. The method of claim 10, the first color filter extending laterally beyond a footprint of the light shield to the second color filter.

13. The method of claim 12, the first color filter extending through the first opening.

14. The method of claim 10, the first color filter having a same filter spectrum as a filter spectrum of the second color filter.

15. The method of claim 10, the first color filter having a different filter spectrum as a filter spectrum of the second color filter.

16. The method of claim 10, further comprising:
forming, over the first at least one photodetector and the second at least one photodetector:
a first at least one microlens corresponding with the first at least one photodetector; and
a second at least one microlens corresponding with the second at least one photodetector.

17. The method of claim 16, wherein:
the first at least one photodetector comprises two first photodetectors;
the second at least one photodetector comprises two second photodetectors;
the light shield covers one of the two first photodetectors;
the first at least one microlens comprises one first microlens; and
the second at least one microlens comprises one second microlens.

18. The method of claim 16, wherein:
the first at least one photodetector comprises two first photodetectors;
the second at least one photodetector comprises two second photodetectors;
the light shield covers one of the two first photodetectors;
the first at least one microlens comprises one first microlens; and
the second at least one microlens comprises two second microlenses.

19. The method of claim 16, wherein:
the first at least one photodetector comprises one first photodetector;
the second at least one photodetector comprises one second photodetector;
the light shield partially covers the one first photodetector;
the first at least one microlens comprises one first microlens; and
the second at least one microlens comprises one second microlens.

20. The method of claim 16, wherein:
the first at least one microlens is laterally aligned with the first at least one photodetector based on a chief ray angle associated with the phase detection pixel; and
the second at least one microlens is laterally aligned with the second at least one photodetector based on a chief ray angle associated with the color pixel.
